(19) United States
(12) Patent Application Publication
(10) Pub. No.: US 2022/0107332 A1
(43) Pub. Date: Apr. 7, 2022

(54) A REMOTE CONTROL METHOD OF SAMPLE PREPARATION AND/OR SAMPLE ANALYSIS

(71) Applicant: MSSCORPS CO., LTD., Hsinchu (TW)

(72) Inventors: CHI-LUN LIU, Hsinchu (TW); DE-KAI WANG, Hsinchu (TW); HSIN-SHENG LIAO, Hsinchu (TW)

(73) Assignee: MSSCORPS CO., LTD., Hsinchu (TW)

(21) Appl. No.: 17/409,765

(22) Filed: Aug. 23, 2021

(30) Foreign Application Priority Data
Oct. 6, 2020 (TW) 109134595

(51) Int. Cl. G01N 35/00; G05B 15/02

(52) U.S. Cl. CPC G01N 35/00871; G05B 15/02; G01Q 60/24; G01N 2035/0091; G01N 2035/00881

(57) ABSTRACT

The present invention provides a remote control method of sample preparation and/or sample analysis, which is characterized by synchronously operating a control apparatus in a guest system comprising a sample preparation apparatus and/or sample analysis apparatus through a host computer installed with a remote control software in a host system when the control apparatus in the host system is operated, therefore the sample preparation apparatus and/or sample analysis apparatus can be performed through the synchronously operated control apparatus in the guest system.

This application claims the benefit of Taiwanese application serial No. 109134595, filed on Oct. 6, 2020, the subject matter of which is incorporated herein by reference.

### BACKGROUND OF THE INVENTION

### Field of the Invention

The invention relates in general to a method of sample preparation and/or sample analysis, and in particular to a remote control method of sample preparation and/or sample analysis.

### Description of the Related Art

Apparatuses for sample preparation and/or sample analysis include Electron Beam Microscope (EBM), Ion Beam Microscope (IBM), Dual Particle Beam Microscope (DPBM), Atomic Force Microscope (AFM), Mass Spectrometer, Energy Scattering Spectrometer (EDS), 3D Laser Confocal Profiler or X-ray Photoelectron Spectroscope (XPS), etc., are precise material analysis instruments, which are expensive and equipped with high-end computers, special control cards and special keyboards, so the operators thereof need be professionally trained to operate this kind of precise sample preparation and/or sample analysis apparatuses, and must operate on-site. After the sample is put into the sample preparation and/or sample analysis apparatus, the samples is proceeded to subsequent sample preparation and image analysis. However, this operation mode is unfavorable to provide services across plants or even multinational companies.

Accordingly, a novel method of sample preparation and/or sample analysis which can avoid to above-mentioned disadvantages is highly expected by the semiconductor industry.

### SUMMARY OF THE INVENTION

This invention provides a remote control method of sample preparation and/or sample analysis, comprising the steps of: providing a guest system, comprising: a sample preparing apparatus and/or a sample analyzing apparatus; a guest computer communicated with the sample preparing apparatus and/or a sample analyzing apparatus; a guest control apparatus, comprising a guest dedicated keyboard, a guest general keyboard and a guest mouse, wherein the guest control apparatus is communicated with the guest computer to control the operation of the sample preparing apparatus and/or a sample analyzing apparatus; providing a host system, comprising: a host computer installed with a remote control software; a host control apparatus comprising a host dedicated keyboard, a host general keyboard and a host mouse, wherein the host control system is communicated with the host computer, and the configurations and the function of the host control apparatus and the guest apparatus are the same; and a host monitor communicated with the host computer; establishing a communication to connect the host system and the guest system through a broadband network, and enable the host system to control the guest system by the remote control software and synchronously display the host monitor and the guest monitor thereafter; providing a sample to be prepared and/or to be analyzed, and moving the sample to be treated and/or to be analyzed into the sample preparing apparatus and/or the sample analyzing apparatus; and synchronously operating the guest control apparatus when operating the host control apparatus of the host system through the host computer and the remote control software, and enabling the sample preparing apparatus and/or sample analyzing apparatus to proceed subsequent sample preparation and/or sample analysis through the synchronously operated guest control apparatus.

The above-mentioned remote control method of sample preparation and/or sample analysis as claimed in claim 1, wherein the ample preparing apparatus and/or a sample analyzing apparatus is an Electron Beam Microscope (EBM), an Ion Beam Microscope (IBM), a Dual Particle Beam Microscope (DPBM), an Atomic Force Microscope (AFM), a Mass Spectrometer, a Energy Dispersive Spectrometer (EDS), a 3D Laser confocal profile or a X-ray photoelectron spectroscopy (XPS)

The above-mentioned remote control method of sample preparation and/or sample analysis as claimed in claim 2, wherein the Electron Beam Microscope (EBM) is a Scanning Electron Microscope (SEM), a Transmission Electron Microscope (TEM), a Scanning Electron Microscopy/Energy Dispersive Spectrometer (SEM/EDS) or a Transmission Electron Microscopy/Energy Dispersive Spectrometer (TEM/EDS).

The above-mentioned remote control method of sample preparation and/or sample analysis as claimed in claim 2, wherein the Ion Beam Microscope (IBM) is a Focused Ion Beam Microscope (FIB) or a Plasma Focused Ion Beam Microscope (PFIB).

The above-mentioned remote control method of sample preparation and/or sample analysis as claimed in claim 2, wherein the Dual Particle Beam Microscope (DPBM) is a Dual Beam Focused Ion Beam Microscope (Dual Beam FIB) or a Dual Beam Focused Ion Beam/Energy Dispersive Spectrometer (Dual Beam FIB/EDS).

The above-mentioned remote control method of sample preparation and/or sample analysis as claimed in claim 1, wherein the guest dedicated keyboard comprises a scan mode selection button, a sample position adjustment button, a scan image contrast adjustment button, an image brightness adjustment button, an image magnification adjustment button, a focus adjustment button, an aberration adjustment button, and an image position adjustment button.

The above-mentioned remote control method of sample preparation and/or sample analysis as claimed in claim 1, wherein the host dedicated keyboard comprises a scan mode selection button, a sample position adjustment button, a scan image contrast adjustment button, an image brightness adjustment button, an image magnification adjustment button, a focus adjustment button, an aberration adjustment button, and an image position adjustment button.

The above-mentioned remote control method of sample preparation and/or sample analysis as claimed in claim 1, wherein the guest system further comprises a guest auxiliary system including an auxiliary computer communicated with the guest computer, and an auxiliary input/output apparatus communicated with the auxiliary computer, which enables the analyzing data obtained from the guest computer can be further backed up, processed or transferred by the guest auxiliary apparatus.

The above-mentioned remote control method of sample preparation and/or sample analysis as claimed in claim 8, wherein the auxiliary input/output apparatus is an auxiliary keyboard, and/or a storage device, and/or an auxiliary mouse.

The above-mentioned remote control method of sample preparation and/or sample analysis as claimed in claim 1, wherein the remote control software is TeamViewer, Chrome Remote Desktop, Splashtop, Microsoft Remote Desktop, TightVNC, Radmin, USB Over Ethernet, DAEMON Tools USB, USB Network Gate, Mikogo, AnyDesk or Wayk Now.

The above-mentioned remote control method of sample preparation and/or sample analysis as claimed in [0004] to [0013], wherein the host system comprises two remote control software installed therein, wherein one of the remote control software is used to enable the guest dedicated keyboard of the guest control apparatus be controlled by the host dedicated keyboard of the host control apparatus after the communication between the guest system and the host system is established through the broadband network, and the other one of the remote control software is used to enable the guest general keyboard and the guest mouse of the guest control apparatus be controlled by the host general keyboard and the host mouse of the host control apparatus after the communication between the guest system and the host system is established through the broadband network.

### BRIEF DESCRIPTION OF THE DRAWINGS

FIG. 1 illustrates a remote control method of sample preparation and/or sample analysis according to Embodiment 1 of this invention.

FIG. 2 illustrates a remote control method of sample preparation and/or sample analysis according to Embodiment 2 of this invention.

FIG. 3 illustrates a remote control method of sample preparation and/or sample analysis according to Embodiment 3 of this invention.

FIG. 4 illustrates a remote control method of sample preparation and/or sample analysis according to Embodiment 4 of this invention.

### DETAILED DESCRIPTION OF THE INVENTION

The detailed description provided below in connection with the appended drawings is intended as a description of the present examples and is not intended to represent the only forms in which the present example may be constructed or utilized. The description sets forth the functions of the example and the sequence of steps for constructing and operation the example. However, the same or equivalent functions and sequences may be accomplished by different examples.

In the following description, numerous specific details are described in detail in order to enable the reader to fully understand the following examples. However, embodiments of the present invention may be practiced in case no such specific details. In other cases, in order to simplify the drawings the structure of the apparatus known only schematically depicted in figures.

### Embodiment

Embodiments 1 and 2 will disclose remote control methods of sample preparation and/or sample analysis which are characterized by having one remote control software installed in the host system; Embodiments 3 and 4 will disclose remote control methods of sample preparation and/or sample analysis which are characterized by having two remote control software installed in the host system. However, the number of software installed in the host system can be adjusted based on different needs.

### Embodiment 1

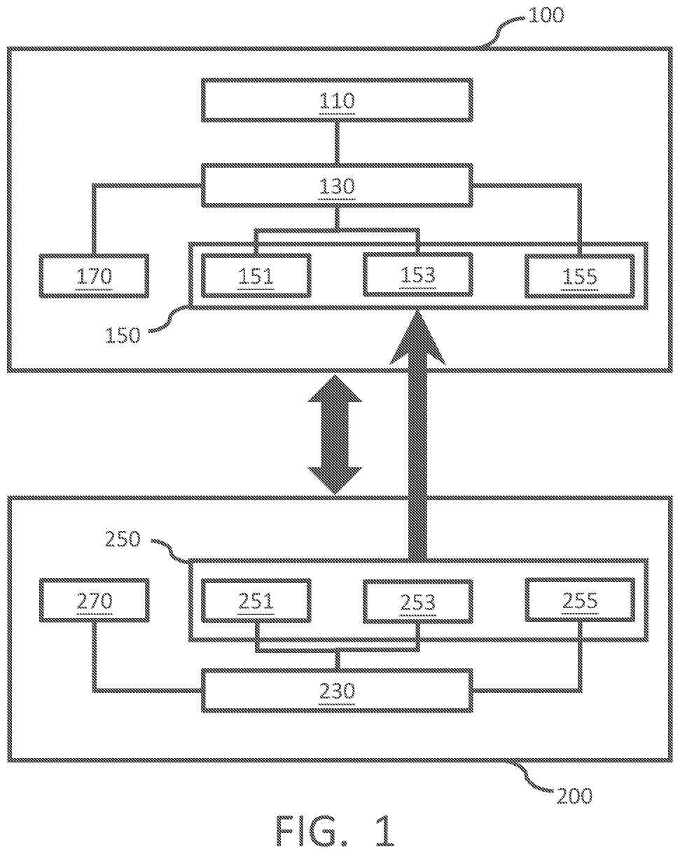

Please refer to FIG. 1, which illustrates a remote control method of sample preparation and/or sample analysis according to Embodiment 1 of this invention.

As shown in FIG. 1, a guest system 100 was provided, which comprises a sample preparing apparatus and/or a sample analyzing apparatus 110, a guest computer communicated with the sample preparing apparatus and/or a sample analyzing apparatus 130, a guest control apparatus 150 comprising a guest dedicated keyboard 151, a guest general keyboard 153 and a guest mouse 155, wherein the guest control apparatus 150 is communicated with the guest computer 130 to control the operation of the sample preparing apparatus and/or a sample analyzing apparatus 110, and a guest monitor 170 which is communicated with the guest computer 130 used to display the parameters input during the operation of the sample preparing apparatus and/or a sample analyzing apparatus 110 and results after analysis. As shown in FIG. 1, a host system 200 was provided, which comprises a host computer 230 installed with a remote control software (not shown), a host control apparatus 250 comprising a host dedicated keyboard 251, a host general keyboard 253 and a host mouse 255, wherein the host control apparatus 250 is communicated with the host computer 230, and the configurations and the function of the host control apparatus 250 and the guest apparatus 150 are the same, and a host monitor 270 communicated with the host computer 230. As shown in FIG. 1, after a communication was established to connect the host system 200 and the guest system 100 through a broadband network (not shown), the host system 200 was enabled to control the guest system 100 by the remote control software (not shown) and synchronously display the host monitor 270 and the guest monitor 170 thereafter. Next, a sample to be prepared and/or to be analyzed (not shown) was provided and moved into the sample preparing apparatus and/or the sample analyzing apparatus 110. Finally, the guest control apparatus 150 of the guest system 100 was synchronously operated when the host control apparatus 250 of the host system 200 was operated through the host computer 230 and the remote control software (not shown), and the sample preparing apparatus and/or sample analyzing apparatus 110 was enabled to proceed subsequent sample preparation and/or sample analysis through the synchronously operated guest control apparatus 150.

The above-mentioned remote control method of sample preparation and/or sample analysis according to above-mentioned Embodiment 1 of this invention, wherein the ample preparing apparatus and/or a sample analyzing apparatus 110 can be an Electron Beam Microscope (EBM), an Ion Beam Microscope (IBM), a Dual Particle Beam Microscope (DPBM), an Atomic Force Microscope (AFM), a Mass Spectrometer, a Energy Dispersive Spectrometer (EDS), a 3D Laser confocal profile or a X-ray photoelectron spectroscopy (XPS). The Electron Beam Microscope (EBM) can be for example but not limited to a Scanning Electron Microscope (SEM), a Transmission Electron Microscope (TEM), a Scanning Electron Microscopy/Energy Dispersive Spectrometer (SEM/EDS) or a Transmission Electron Microscopy/Energy Dispersive Spectrometer (TEM/EDS). The Ion Beam Microscope (IBM) can be for example but not limited to a Focused Ion Beam Microscope (FIB) or a Plasma Focused Ion Beam Microscope (PFIB). The Dual Particle Beam Microscope (DPBM) can be for example but not limited to a Dual Beam Focused Ion Beam Microscope (Dual Beam FIB) or a Dual Beam Focused Ion Beam/Energy Dispersive Spectrometer (Dual Beam FIB/EDS).

The above-mentioned remote control method of sample preparation and/or sample analysis according to above-mentioned Embodiment 1 of this invention, wherein the guest dedicated keyboard 151 comprises for example but not limited to a scan mode selection button (not shown), a sample position adjustment button (not shown), a scan image contrast adjustment button (not shown), an image brightness adjustment button (not shown), an image magnification adjustment button (not shown), a focus adjustment button (not shown), an aberration adjustment button (not shown), and an image position adjustment button (not shown).

The above-mentioned remote control method of sample preparation and/or sample analysis according to above-mentioned Embodiment 1 of this invention, wherein the host dedicated keyboard 251 comprises for example but not limited to a scan mode selection button (not shown), a sample position adjustment button (not shown), a scan image contrast adjustment button (not shown), an image brightness adjustment button (not shown), an image magnification adjustment button (not shown), a focus adjustment button (not shown), an aberration adjustment button (not shown), and an image position adjustment button (not shown).

The above-mentioned remote control method of sample preparation and/or sample analysis according to above-mentioned Embodiment 1 of this invention, wherein the remote control software (not shown) can be for example but not limited to TeamViewer, Chrome Remote Desktop, Splashtop, Microsoft Remote Desktop, TightVNC, Radmin, USB Over Ethernet, DAEMON Tools USB, USB Network Gate, Mikogo, AnyDesk or Wayk Now.

### Embodiment 2

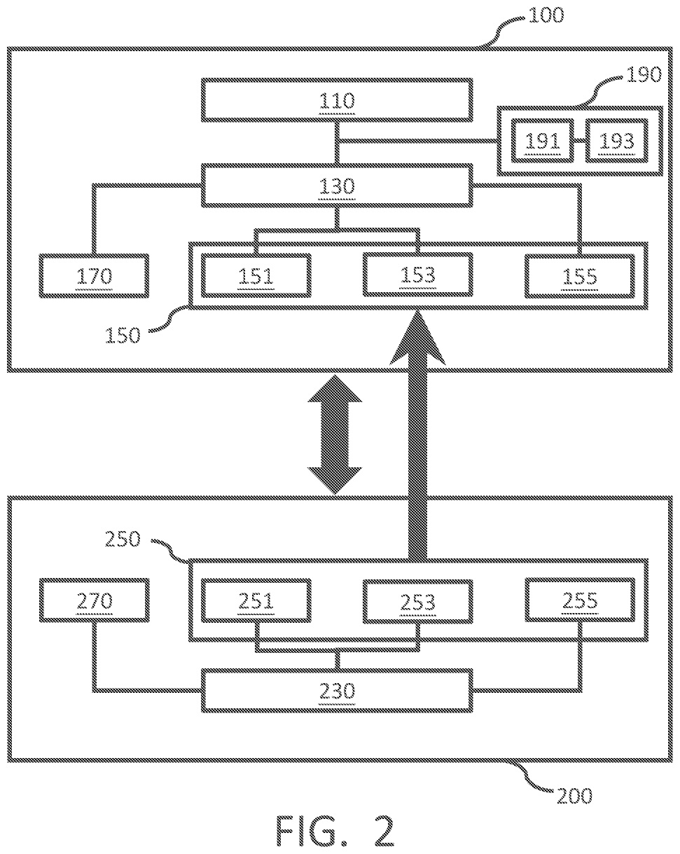

Please refer to FIG. 2, which illustrates a remote control method of sample preparation and/or sample analysis according to Embodiment 2 of this invention.

As shown in FIG. 2, a guest system 100 was provided, which comprises a sample preparing apparatus and/or a sample analyzing apparatus 110, a guest computer communicated with the sample preparing apparatus and/or a sample analyzing apparatus 130, a guest control apparatus 150 comprising a guest dedicated keyboard 151, a guest general keyboard 153 and a guest mouse 155, wherein the guest control apparatus 150 is communicated with the guest computer 130 to control the operation of the sample preparing apparatus and/or a sample analyzing apparatus 110, a guest monitor 170 which is communicated with the guest computer 130 used to display the parameters input during the operation of the sample preparing apparatus and/or a sample analyzing apparatus 110 and results after analysis, and a guest auxiliary apparatus 190 comprising an auxiliary computer 191 communicated with the guest computer 130 and an auxiliary input/output apparatus 193 communicated with the auxiliary computer, which enables the analyzing data obtained from the guest computer can be further backed up, processed or transferred by the guest auxiliary apparatus. As shown in FIG. 2, a host system 200 was provided, which comprises a host computer 230 installed with a remote control software (not shown), a host control apparatus 250 comprising a host dedicated keyboard 251, a host general keyboard 253 and a host mouse 255, wherein the host control apparatus 250 is communicated with the host computer 230, and the configurations and the function of the host control apparatus 250 and the guest apparatus 150 are the same, and a host monitor 270 communicated with the host computer 230. As shown in FIG. 2, after a communication was established to connect the host system 200 and the guest system 100 through a broadband network (not shown), the host system 200 was enabled to control the guest system 100 by the remote control software (not shown) and synchronously display the host monitor 270 and the guest monitor 170 thereafter. Next, a sample to be prepared and/or to be analyzed (not shown) was provided and moved into the sample preparing apparatus and/or the sample analyzing apparatus 110. Finally, the guest control apparatus 150 of the guest system 100 was synchronously operated when the host control apparatus 250 of the host system 200 was operated through the host computer 230 and the remote control software (not shown), and the sample preparing apparatus and/or sample analyzing apparatus 110 was enabled to proceed subsequent sample preparation and/or sample analysis through the synchronously operated guest control apparatus 150.

The above-mentioned remote control method of sample preparation and/or sample analysis according to above-mentioned Embodiment 2 of this invention, wherein the ample preparing apparatus and/or a sample analyzing apparatus 110 can be an Electron Beam Microscope (EBM), an Ion Beam Microscope (IBM), a Dual Particle Beam Microscope (DPBM), an Atomic Force Microscope (AFM), a Mass Spectrometer, a Energy Dispersive Spectrometer (EDS), a 3D Laser confocal profile or a X-ray photoelectron spectroscopy (XPS). The Electron Beam Microscope (EBM) can be for example but not limited to a Scanning Electron Microscope (SEM), a Transmission Electron Microscope (TEM), a Scanning Electron Microscopy/Energy Dispersive Spectrometer (SEM/EDS) or a Transmission Electron Microscopy/Energy Dispersive Spectrometer (TEM/EDS). The Ion Beam Microscope (IBM) can be for example but not limited to a Focused Ion Beam Microscope (FIB) or a Plasma Focused Ion Beam Microscope (PFIB). The Dual Particle Beam Microscope (DPBM) can be for example but not limited to a Dual Beam Focused Ion Beam Microscope (Dual Beam FIB) or a Dual Beam Focused Ion Beam/Energy Dispersive Spectrometer (Dual Beam FIB/EDS).

The above-mentioned remote control method of sample preparation and/or sample analysis according to above-mentioned Embodiment 2, wherein the auxiliary input/output apparatus 193 can be for example but not limited to an auxiliary keyboard, and/or a storage device, and/or an auxiliary mouse.

The above-mentioned remote control method of sample preparation and/or sample analysis according to above-mentioned Embodiment 2 of this invention, wherein the guest dedicated keyboard 151 comprises for example but not limited to a scan mode selection button (not shown), a sample position adjustment button (not shown), a scan image contrast adjustment button (not shown), an image brightness adjustment button (not shown), an image magnification adjustment button (not shown), a focus adjustment button (not shown), an aberration adjustment button (not shown), and an image position adjustment button (not shown).

The above-mentioned remote control method of sample preparation and/or sample analysis according to above-mentioned Embodiment 2 of this invention, wherein the host dedicated keyboard 251 comprises for example but not limited to a scan mode selection button (not shown), a sample position adjustment button (not shown), a scan image contrast adjustment button (not shown), an image brightness adjustment button (not shown), an image magnification adjustment button (not shown), a focus adjustment button (not shown), an aberration adjustment button (not shown), and an image position adjustment button (not shown).

The above-mentioned remote control method of sample preparation and/or sample analysis according to above-mentioned Embodiment 2 of this invention, wherein the remote control software (not shown) can be for example but not limited to TeamViewer, Chrome Remote Desktop, Splashtop, Microsoft Remote Desktop, TightVNC, Radmin, USB Over Ethernet, DAEMON Tools USB, USB Network Gate, Mikogo, AnyDesk or Wayk Now.

### Embodiment 3

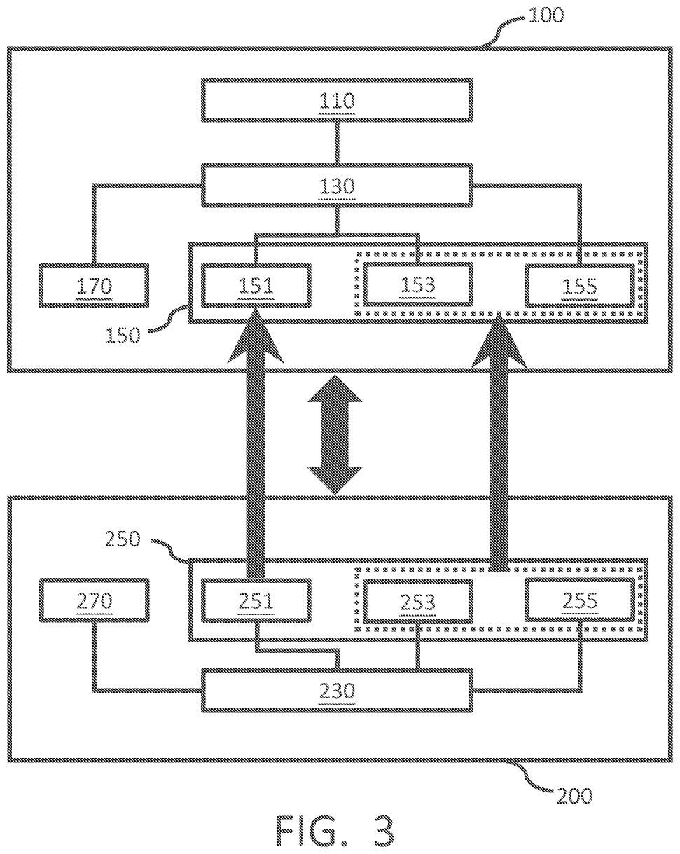

Please refer to FIG. 3, which illustrates a remote control method of sample preparation and/or sample analysis according to Embodiment 3 of this invention.

As shown in FIG. 3, a guest system 100 was provided, which comprises a sample preparing apparatus and/or a sample analyzing apparatus 110, a guest computer communicated with the sample preparing apparatus and/or a sample analyzing apparatus 130, a guest control apparatus 150 comprising a guest dedicated keyboard 151, a guest general keyboard 153 and a guest mouse 155, wherein the guest control apparatus 150 is communicated with the guest computer 130 to control the operation of the sample preparing apparatus and/or a sample analyzing apparatus 110, and a guest monitor 170 which is communicated with the guest computer 130 used to display the parameters input during the operation of the sample preparing apparatus and/or a sample analyzing apparatus 110 and results after analysis. As shown in FIG. 3, a host system 200 was provided, which comprises a host computer 230 installed with a remote control software (not shown), a host control apparatus 250 comprising a host dedicated keyboard 251, a host general keyboard 253 and a host mouse 255, wherein the host control apparatus 250 is communicated with the host computer 230, and the configurations and the function of the host control apparatus 250 and the guest apparatus 150 are the same, and a host monitor 270 communicated with the host computer 230. As shown in FIG. 3, after a communication was established to connect the host system 200 and the guest system 100 through a broadband network (not shown), the host system 200 was enabled to control the guest system 100 by the remote control software (not shown) and synchronously display the host monitor 270 and the guest monitor 170 thereafter. Next, a sample to be prepared and/or to be analyzed (not shown) was provided and moved into the sample preparing apparatus and/or the sample analyzing apparatus 110. Finally, the guest control apparatus 150 of the guest system 100 was synchronously operated when the host control apparatus 250 of the host system 200 was operated through the host computer 230 and the remote control software (not shown), and the sample preparing apparatus and/or sample analyzing apparatus 110 was enabled to proceed subsequent sample preparation and/or sample analysis through the synchronously operated guest control apparatus 150.

The above-mentioned remote control method of sample preparation and/or sample analysis according to above-mentioned Embodiment 3 of this invention, wherein the ample preparing apparatus and/or a sample analyzing apparatus 110 can be an Electron Beam Microscope (EBM), an Ion Beam Microscope (IBM), a Dual Particle Beam Microscope (DPBM), an Atomic Force Microscope (AFM), a Mass Spectrometer, a Energy Dispersive Spectrometer (EDS), a 3D Laser confocal profile or a X-ray photoelectron spectroscopy (XPS). The Electron Beam Microscope (EBM) can be for example but not limited to a Scanning Electron Microscope (SEM), a Transmission Electron Microscope (TEM), a Scanning Electron Microscopy/Energy Dispersive Spectrometer (SEM/EDS) or a Transmission Electron Microscopy/Energy Dispersive Spectrometer (TEM/EDS). The Ion Beam Microscope (IBM) can be for example but not limited to a Focused Ion Beam Microscope (FIB) or a Plasma Focused Ion Beam Microscope (PFIB). The Dual Particle Beam Microscope (DPBM) can be for example but not limited to a Dual Beam Focused Ion Beam Microscope (Dual Beam FIB) or a Dual Beam Focused Ion Beam/Energy Dispersive Spectrometer (Dual Beam FIB/EDS).

The above-mentioned remote control method of sample preparation and/or sample analysis according to above-mentioned Embodiment 3 of this invention, wherein the guest dedicated keyboard 151 comprises for example but not limited to a scan mode selection button (not shown), a sample position adjustment button (not shown), a scan image contrast adjustment button (not shown), an image brightness adjustment button (not shown), an image magnification adjustment button (not shown), a focus adjustment button (not shown), an aberration adjustment button (not shown), and an image position adjustment button (not shown).

The above-mentioned remote control method of sample preparation and/or sample analysis according to above-mentioned Embodiment 3 of this invention, wherein the host dedicated keyboard 251 comprises for example but not limited to a scan mode selection button (not shown), a sample position adjustment button (not shown), a scan image contrast adjustment button (not shown), an image brightness adjustment button (not shown), an image magnification adjustment button (not shown), a focus adjustment button (not shown), an aberration adjustment button (not shown), and an image position adjustment button (not shown).

The above-mentioned remote control method of sample preparation and/or sample analysis according to above-mentioned Embodiment 3 of this invention, wherein the remote control software (not shown) can be for example but not limited to TeamViewer, Chrome Remote Desktop, Splashtop, Microsoft Remote Desktop, TightVNC, Radmin, USB Over Ethernet, DAEMON Tools USB, USB Network Gate, Mikogo, AnyDesk or Wayk Now.

The above-mentioned remote control method of sample preparation and/or sample analysis according to above-mentioned Embodiment 3 of this invention, wherein the host system 200 comprises two remote control software (not shown) installed therein, wherein one of the remote control software (not shown) is used to enable the guest dedicated keyboard 151 of the guest control apparatus 150 be controlled by the host dedicated keyboard 251 of the host control apparatus 250 after the communication between the guest system 100 and the host system 200 is established through the broadband network, and the other one of the remote control software (not shown) is used to enable the guest general keyboard 153 and the guest mouse 155 of the guest control apparatus 150 be controlled by the host general keyboard 253 and the host mouse 255 of the host control apparatus 250 after the communication between the guest system 100 and the host system 200 is established through the broadband network.

### Embodiment 4

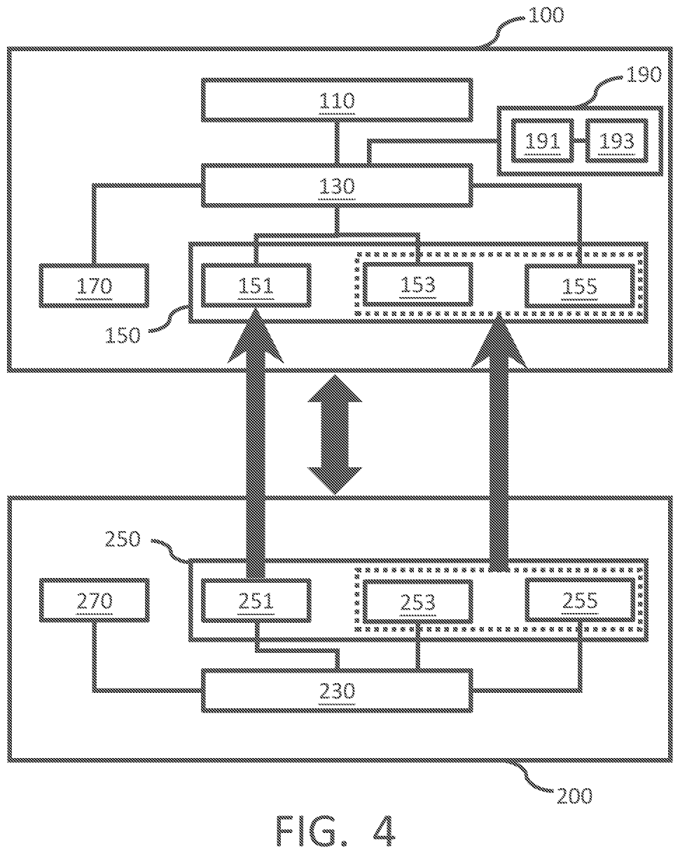

Please refer to FIG. 4, which illustrates a remote control method of sample preparation and/or sample analysis according to Embodiment 4 of this invention.

As shown in FIG. 4, a guest system 100 was provided, which comprises a sample preparing apparatus and/or a sample analyzing apparatus 110, a guest computer communicated with the sample preparing apparatus and/or a sample analyzing apparatus 130, a guest control apparatus 150 comprising a guest dedicated keyboard 151, a guest general keyboard 153 and a guest mouse 155, wherein the guest control apparatus 150 is communicated with the guest computer 130 to control the operation of the sample preparing apparatus and/or a sample analyzing apparatus 110, a guest monitor 170 which is communicated with the guest computer 130 used to display the parameters input during the operation of the sample preparing apparatus and/or a sample analyzing apparatus 110 and results after analysis, and a guest auxiliary apparatus 190 comprising an auxiliary computer 191 communicated with the guest computer 130 and an auxiliary input/output apparatus 193 communicated with the auxiliary computer, which enables the analyzing data obtained from the guest computer can be further backed up, processed or transferred by the guest auxiliary apparatus. As shown in FIG. 4, a host system 200 was provided, which comprises a host computer 230 installed with a remote control software (not shown), a host control apparatus 250 comprising a host dedicated keyboard 251, a host general keyboard 253 and a host mouse 255, wherein the host control apparatus 250 is communicated with the host computer 230, and the configurations and the function of the host control apparatus 250 and the guest apparatus 150 are the same, and a host monitor 270 communicated with the host computer 230. As shown in FIG. 4, after a communication was established to connect the host system 200 and the guest system 100 through a broadband network (not shown), the host system 200 was enabled to control the guest system 100 by the remote control software (not shown) and synchronously display the host monitor 270 and the guest monitor 170 thereafter. Next, a sample to be prepared and/or to be analyzed (not shown) was provided and moved into the sample preparing apparatus and/or the sample analyzing apparatus 110. Finally, the guest control apparatus 150 of the guest system 100 was synchronously operated when the host control apparatus 250 of the host system 200 was operated through the host computer 230 and the remote control software (not shown), and the sample preparing apparatus and/or sample analyzing apparatus 110 was enabled to proceed subsequent sample preparation and/or sample analysis through the synchronously operated guest control apparatus 150.

The above-mentioned remote control method of sample preparation and/or sample analysis according to above-mentioned Embodiment 4 of this invention, wherein the ample preparing apparatus and/or a sample analyzing apparatus 110 can be an Electron Beam Microscope (EBM), an Ion Beam Microscope (IBM), a Dual Particle Beam Microscope (DPBM), an Atomic Force Microscope (AFM), a Mass Spectrometer, a Energy Dispersive Spectrometer (EDS), a 3D Laser confocal profile or a X-ray photoelectron spectroscopy (XPS). The Electron Beam Microscope (EBM) can be for example but not limited to a Scanning Electron Microscope (SEM), a Transmission Electron Microscope (TEM), a Scanning Electron Microscopy/Energy Dispersive Spectrometer (SEM/EDS) or a Transmission Electron Microscopy/Energy Dispersive Spectrometer (TEM/EDS). The Ion Beam Microscope (IBM) can be for example but not limited to a Focused Ion Beam Microscope (FIB) or a Plasma Focused Ion Beam Microscope (PFIB). The Dual Particle Beam Microscope (DPBM) can be for example but not limited to a Dual Beam Focused Ion Beam Microscope (Dual Beam FIB) or a Dual Beam Focused Ion Beam/Energy Dispersive Spectrometer (Dual Beam FIB/EDS).

The above-mentioned remote control method of sample preparation and/or sample analysis according to above-mentioned Embodiment 4, wherein the auxiliary input/output apparatus 193 can be for example but not limited to an auxiliary keyboard, and/or a storage device, and/or an auxiliary mouse.

The above-mentioned remote control method of sample preparation and/or sample analysis according to above-mentioned Embodiment 4 of this invention, wherein the guest dedicated keyboard 151 comprises for example but not limited to a scan mode selection button (not shown), a sample position adjustment button (not shown), a scan image contrast adjustment button (not shown), an image brightness adjustment button (not shown), an image magnification adjustment button (not shown), a focus adjustment button (not shown), an aberration adjustment button (not shown), and an image position adjustment button (not shown).

The above-mentioned remote control method of sample preparation and/or sample analysis according to above-mentioned Embodiment 4 of this invention, wherein the host dedicated keyboard 251 comprises for example but not limited to a scan mode selection button (not shown), a sample position adjustment button (not shown), a scan image contrast adjustment button (not shown), an image brightness adjustment button (not shown), an image magnification adjustment button (not shown), a focus adjustment button (not shown), an aberration adjustment button (not shown), and an image position adjustment button (not shown).

The above-mentioned remote control method of sample preparation and/or sample analysis according to above-mentioned Embodiment 4 of this invention, wherein the remote control software (not shown) can be for example but not limited to TeamViewer, Chrome Remote Desktop, Splashtop, Microsoft Remote Desktop, TightVNC, Radmin, USB Over Ethernet, DAEMON Tools USB, USB Network Gate, Mikogo, AnyDesk or Wayk Now.

The above-mentioned remote control method of sample preparation and/or sample analysis according to above-mentioned Embodiment 4 of this invention, wherein the host system 200 comprises two remote control software (not shown) installed therein, wherein one of the remote control software (not shown) is used to enable the guest dedicated keyboard 151 of the guest control apparatus 150 be controlled by the host dedicated keyboard 251 of the host control apparatus 250 after the communication between the guest system 100 and the host system 200 is established through the broadband network, and the other one of the remote control software (not shown) is used to enable the guest general keyboard 153 and the guest mouse 155 of the guest control apparatus 150 be controlled by the host general keyboard 253 and the host mouse 255 of the host control apparatus 250 after the communication between the guest system 100 and the host system 200 is established through the broadband network.

As above-mentioned remote control methods of sample preparation and/or sample analysis according to above-mentioned Embodiments of this invention, when the sample preparation and/or sample analysis apparatus and the trained professional are located at different places A and B, The trained professional located at place B can remotely control the sample preparation and/or sample analysis apparatus at place A to perform subsequent sample preparation and/or sample analysis without visiting the sample preparation and/or sample analysis device located at place A. This operation mode can provide more convenient services for across plants or even multinational companies.

Although particular embodiments have been shown and described, it should be understood that the above discussion is not intended to limit the present invention to these embodiments. Persons skilled in the art will understand that various changes and modifications may be made without departing from the scope of the present invention as literally and equivalently covered by the following claims.

1. A remote control method of sample preparation and/or sample analysis, comprising the steps of:
providing a guest system, comprising:
a sample preparing apparatus and/or a sample analyzing apparatus;
a guest computer communicated with the sample preparing apparatus and/or a sample analyzing apparatus;
a guest control apparatus, comprising a guest dedicated keyboard, a guest general keyboard and a guest mouse, wherein the guest control apparatus is communicated with the guest computer to control the operation of the sample preparing apparatus and/or a sample analyzing apparatus;
providing a host system, comprising:
a host computer installed with a remote control software;
a host control apparatus comprising a host dedicated keyboard, a host general keyboard and a host mouse, wherein the host control system is communicated with the host computer, and the configurations and the function of the host control apparatus and the guest apparatus are the same; and
a host monitor communicated with the host computer;
establishing a communication to connect the host system and the guest system through a broadband network, and enable the host system to control the guest system by the remote control software and synchronously display the host monitor and the guest monitor thereafter;
providing a sample to be prepared and/or to be analyzed, and moving the sample to be treated and/or to be analyzed into the sample preparing apparatus and/or the sample analyzing apparatus; and
synchronously operating the guest control apparatus when operating the host control apparatus of the host system through the host computer and the remote control software, and enabling the sample preparing apparatus and/or sample analyzing apparatus to proceed subsequent sample preparation and/or sample analysis through the synchronously operated guest control apparatus.

2. The remote control method of sample preparation and/or sample analysis as claimed in claim 1, wherein the ample preparing apparatus and/or a sample analyzing apparatus is an Electron Beam Microscope (EBM), an Ion Beam Microscope (IBM), a Dual Particle Beam Microscope (DPBM), an Atomic Force Microscope (AFM), a Mass Spectrometer, a Energy Dispersive Spectrometer (EDS), a 3D Laser confocal profile or a X-ray photoelectron spectroscopy (XPS)

3. The remote control method of sample preparation and/or sample analysis as claimed in claim 2, wherein the Electron Beam Microscope (EBM) is a Scanning Electron Microscope (SEM), a Transmission Electron Microscope (TEM), a Scanning Electron Microscopy/Energy Dispersive Spectrometer (SEM/EDS) or a Transmission Electron Microscopy/Energy Dispersive Spectrometer (TEM/EDS).

4. The remote control method of sample preparation and/or sample analysis as claimed in claim 2, wherein the Ion Beam Microscope (IBM) is a Focused Ion Beam Microscope (FIB) or a Plasma Focused Ion Beam Microscope (PFIB).

5. The remote control method of sample preparation and/or sample analysis as claimed in claim 2, wherein the Dual Particle Beam Microscope (DPBM) is a Dual Beam Focused Ion Beam Microscope (Dual Beam FIB) or a Dual Beam Focused Ion Beam/Energy Dispersive Spectrometer (Dual Beam FIB/EDS).

6. The remote control method of sample preparation and/or sample analysis as claimed in claim 1, wherein the guest dedicated keyboard comprises a scan mode selection button, a sample position adjustment button, a scan image contrast adjustment button, an image brightness adjustment button, an image magnification adjustment button, a focus adjustment button, an aberration adjustment button, and an image position adjustment button.

7. The remote control method of sample preparation and/or sample analysis as claimed in claim 1, wherein the host dedicated keyboard comprises a scan mode selection button, a sample position adjustment button, a scan image contrast adjustment button, an image brightness adjustment button, an image magnification adjustment button, a focus adjustment button, an aberration adjustment button, and an image position adjustment button.

8. The remote control method of sample preparation and/or sample analysis as claimed in claim 1, wherein the guest system further comprises a guest auxiliary system including an auxiliary computer communicated with the guest computer, and an auxiliary input/output apparatus communicated with the auxiliary computer, which enables the analyzing data obtained from the guest computer can be further backed up, processed or transferred by the guest auxiliary apparatus.

9. The remote control method of sample preparation and/or sample analysis as claimed in claim 8, wherein the auxiliary input/output apparatus is an auxiliary keyboard, and/or a storage device, and/or an auxiliary mouse.

10. The remote control method of sample preparation and/or sample analysis as claimed in claim 1, wherein the remote control software is TeamViewer, Chrome Remote Desktop, Splashtop, Microsoft Remote Desktop, TightVNC, Radmin, USB Over Ethernet, DAEMON Tools USB, USB Network Gate, Mikogo, AnyDesk or Wayk Now.

11. The remote control method of sample preparation and/or sample analysis as claimed in claim 1, wherein the host system comprises two remote control software installed therein, wherein one of the remote control software is used to enable the guest dedicated keyboard of the guest control apparatus be controlled by the host dedicated keyboard of the host control apparatus after the communication between the guest system and the host system is established through the broadband network, and the other one of the remote control software is used to enable the guest general keyboard and the guest mouse of the guest control apparatus be controlled by the host general keyboard and the host mouse of the host control apparatus after the communication between the guest system and the host system is established through the broadband network.
